(19) United States
(12) Patent Application Publication
(10) Pub. No.: US 2026/0324292 A1
(43) Pub. Date: Oct. 15, 2026

(54) METHOD OF MANUFACTURING MAGNETORESISTIVE RANDOM ACCESS MEMORY DEVICE INCLUDING FORMING PROTECTIVE LAYER

(71) Applicant: Samsung Electronics Co., Ltd., Suwon-si (KR)

(72) Inventor: Yoonyoung Lee, Suwon-si (KR)

(73) Assignee: Samsung Electronics Co., Ltd., Suwon-si (KR)

(21) Appl. No.: 19/636,370

(22) Filed: Apr. 1, 2026

(30) Foreign Application Priority Data
Apr. 9, 2025 (KR) 10-2025-0046199

(51) Int. Cl. H10N 50/01; G11C 11/16; H10B 61/00; H10N 50/10; H10N 50/85

(52) U.S. Cl. CPC H10N 50/01; H10B 61/22; H10N 50/10; H10N 50/85; G11C 11/161

(57) ABSTRACT

In a method of manufacturing an MRAM device, an MTJ layer structure is formed on an insulating interlayer on a substrate. An upper electrode structure is formed on the MTJ layer structure. An etching process is performed using the upper electrode structure as an etching mask to transform the MTJ layer structure into an MTJ structure and to form a trench at an upper portion of the insulating interlayer, such that a metal layer including a metal generated from the upper electrode structure during the etching process and at least partially covering a sidewall and a bottom of the trench is formed. A first protective layer is formed on a sidewall of the upper electrode structure, a sidewall of the MTJ structure and the sidewall of the trench. An oxidation process is performed on the metal layer to form a metal oxide layer covering the bottom of the trench.

### CROSS-REFERENCE TO RELATED APPLICATIONS

This present application claims priority to and the benefit under 35 U.S.C. § 119(a)-(d) of Korean Patent Application No. 10-2025-0046199, filed on Apr. 9, 2025, in the Korean Intellectual Property Office, the entire disclosure of which is incorporated herein by reference.

### FIELD

Example embodiments of the present disclosure relate to methods of manufacturing magneto-resistive random access memory (MRAM) devices and more particularly to methods of manufacturing MRAM devices including forming a protective layer.

### BACKGROUND

A magneto-resistive random access memory (MRAM) device is a non-volatile memory device that utilizes the magneto-resistive effect, offering advantages such as low power consumption for data retention and excellent endurance. The core component of the MRAM device, the magnetic tunnel junction (MTJ), has a structure in which a thin insulating layer (tunneling barrier) is sandwiched between two ferromagnetic layers. Digital information is stored based on the difference in electrical resistance depending on the relative magnetization directions of the two ferromagnetic layers.

In a method of manufacturing an MRAM device, patterning of the MTJ structure is a critical technical challenge, and in particular, short-circuit issues between adjacent MRAM memory cells directly affect device yield and reliability. Such short-circuit problems mainly arise from metal redeposition during an etching process, sidewall shorting phenomena, or patterning defects, which may act as major obstacles to the realization of highly integrated MRAM device.

### SUMMARY

According to example embodiments of the disclosed concepts, there is a method of manufacturing an MRAM device. In the method, an MTJ layer structure may be formed on an insulating interlayer on a substrate. An upper electrode structure may be formed on the MTJ layer structure. An etching process may be performed using the upper electrode structure as an etching mask to transform the MTJ layer structure into an MTJ structure and to form a trench at an upper portion of the insulating interlayer, such that a metal layer including a metal generated from the upper electrode structure during the etching process and at least partially covering a sidewall and a bottom of the trench may be formed. A first protective layer may be formed on a sidewall of the upper electrode structure, a sidewall of the MTJ structure and the sidewall of the trench. An oxidation process may be performed on the metal layer to form a metal oxide layer at least partially covering the bottom of the trench.

According to example embodiments of the disclosed concepts, there is a method of manufacturing an MRAM device. In the method, a lower electrode layer and an MTJ layer structure may be formed on an insulating interlayer on a substrate. An upper electrode structure may be formed on the MTJ layer structure. An etching process may be formed using the upper electrode structure as an etching mask to transform the MTJ layer structure and the lower electrode layer into an MTJ structure and a lower electrode, respectively, and to form a trench at an upper portion of the insulating interlayer, such that a metal layer including a metal generated from the upper electrode structure during the etching process and at least partially covering a sidewall and a bottom of the trench may be formed. A first protective layer may be formed on an upper surface and a sidewall of the upper electrode structure, a sidewall of the MTJ structure, a sidewall of the lower electrode, and the sidewall and the bottom of the trench. An anisotropic etching process may be performed on the first protective layer to expose a first portion of the metal layer on the bottom of the trench. A cleaning process may be formed on the first portion of the metal layer.

According to example embodiments of the disclosed concepts, there is a method of manufacturing an MRAM device. In the method a lower electrode layer, an MTJ layer structure and a capping layer may be formed on an insulating interlayer on a substrate. An upper electrode structure including a first upper electrode and a second upper electrode sequentially stacked on the capping layer may be formed. An etching process may be performed using the upper electrode structure as an etching mask to transform the capping layer, the MTJ layer structure and the lower electrode layer into a capping pattern, an MTJ structure and a lower electrode, respectively, and to form a trench at an upper portion of the insulating interlayer, such that a metal layer including a first metal and a second metal generated from the capping pattern and the upper electrode structure, respectively, during the etching process and at least partially covering a sidewall and a bottom of the trench may be formed. A first protective layer may be formed on a sidewall of the upper electrode structure, a sidewall of the capping pattern, a sidewall of the MTJ structure, a sidewall of the lower electrode and the sidewall of the trench. A cleaning process may be performed on a first portion of the metal layer on the bottom of the trench. An oxidation process may be performed on the first portion of the metal layer remaining after the cleaning process to form a metal oxide layer. The first metal of the metal layer may be removed during the cleaning process.

### BRIEF DESCRIPTION OF THE DRAWINGS

FIGS. 1 and 2 are cross-sectional views illustrating an MRAM device in accordance with example embodiments. FIG. 2 is an enlarged cross-sectional view of region X of FIG. 1.

FIGS. 3 to 11 are cross-sectional views illustrating a method of manufacturing an MRAM device in accordance with example embodiments.

FIG. 12 is a cross-sectional view illustrating an MRAM device in accordance with example embodiments.

FIGS. 13 and 14 are cross-sectional views illustrating a method of manufacturing an MRAM device in accordance with example embodiments.

FIG. 15 is a cross-sectional view illustrating an MRAM device in accordance with example embodiments.

FIG. 16 is a cross-sectional view illustrating an MRAM device in accordance with example embodiments.

FIG. 17 is a cross-sectional view illustrating an MRAM device in accordance with example embodiments.

FIG. 18 is a cross-sectional view illustrating an MRAM device in accordance with example embodiments.

FIGS. 19 and 20 are a cross-sectional view and a perspective view, respectively, illustrating an MRAM device in accordance with example embodiments.

### DETAILED DESCRIPTION

Hereinafter, example embodiments will be described in detail with reference to the accompanying drawings. It will be understood that, although the terms “first,” “second,” and/or “third” may be used herein to describe various elements, these elements should not be limited by these terms. These terms are only used to distinguish one element from another element.

In the specifications (and not necessarily in the claims), two directions among horizontal directions that are substantially parallel to an upper surface of a substrate, which may intersect each other, may be referred to as first and second directions D1 and D2, respectively, and a vertical direction that is substantially perpendicular to the upper surface of the substrate may be referred to as a third direction D3. In example embodiments, the first and second directions D1 and D2 may be substantially perpendicular to each other. Each of the first to third directions D1, D2 and D3 may include a direction shown in the drawings and a direction inverse thereto.

Example embodiments provide a method of manufacturing an MRAM device having improved characteristics.

In the method of manufacturing the MRAM device, a cleaning process and/or an oxidation process may be performed on a metal layer redeposited on a surface of an insulating interlayer between neighboring memory cells during patterning the MTJ layer structure. Thus, an electric short circuit between the neighboring memory cells may be reduced.

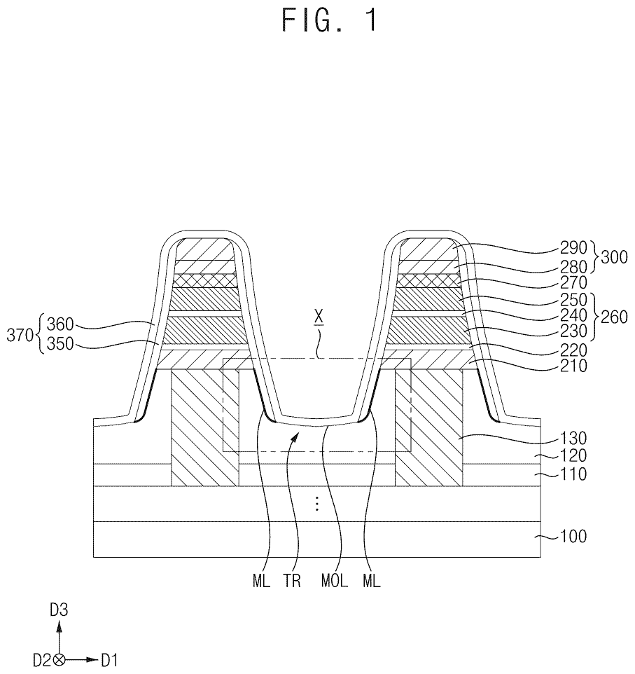

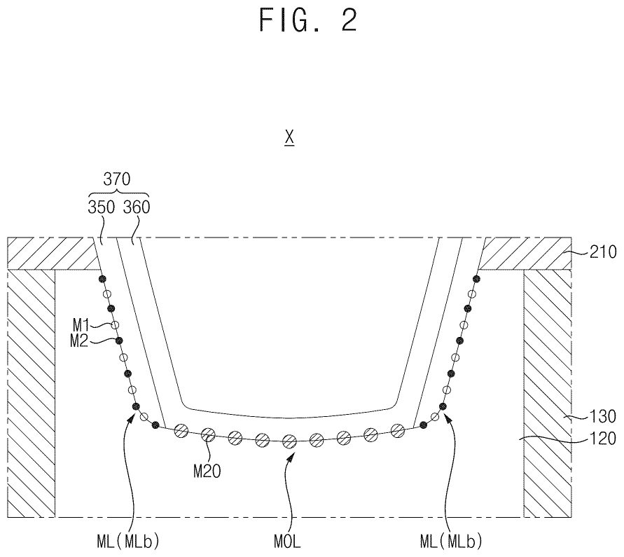

FIGS. 1 and 2 are cross-sectional views illustrating an MRAM device in accordance with example embodiments. FIG. 2 is an enlarged cross-sectional view of region X of FIG. 1.

Referring to FIGS. 1 and 2, the MRAM device may include a substrate 100, a barrier layer 110, a first insulating interlayer 120, a metal layer ML, a metal oxide layer MOL, lower electrode contacts 130, memory cells and a protective layer structure 370.

The substrate 100 may include a semiconductor material, e.g., silicon, germanium, silicon-germanium, or III-V semiconductor compounds, e.g., GaP, GaAs, GaSb, etc. In example embodiments, the substrate 100 may be a silicon-on-insulator (SOI) substrate or a germanium-on-insulator (GOI) substrate.

The barrier layer 110 and the first insulating interlayer 120 may be sequentially stacked on an upper surface of the substrate 100. Various types of elements (not shown), e.g. transistors, contact plugs, wirings, vias, etc., may be disposed between the upper surface of the substrate 100 and a lower surface of the barrier layer 110. The barrier layer 110 may include, e.g., silicon carbonitride. The first insulating interlayer 120 may include an oxide, e.g., silicon oxide.

A trench TR may be formed on the first insulating interlayer 120. The trench TR may be disposed between the memory cells neighboring in the first direction D1 or in the second direction D2, and may extend into the first insulating interlayer 120 from an upper surface of the first insulating interlayer 120.

The trench TR may include a bottom and a sidewall. The bottom of the trench TR may be lower than the upper surface of the first insulating interlayer 120. The sidewall of the trench TR may connect the bottom of the trench TR and the upper surface of the first insulating interlayer 120. In example embodiments, the sidewall of the trench TR may be connected to sidewalls of the memory cells. In example embodiments, the sidewall of the trench TR may be slanted with respect to the upper surface of the substrate 100.

FIG. 1 shows that the bottom of the trench TR is higher than an upper surface of the barrier layer 110, however, the disclosed concepts are not limited thereto. That is, the bottom of the trench TR may be lower than the upper surface of the barrier layer 110.

The metal layer ML may at least partially cover the sidewall of the trench TR. In example embodiments, the metal layer ML may at least partially cover the sidewall and an edge of the bottom of the trench TR.

The metal oxide layer MOL at least partially cover the bottom of the trench TR. In example embodiments, the metal oxide layer MOL may at least partially cover a central portion of the bottom of the trench TR.

The metal layer ML may include a first metal M1 and a second metal M2. The metal oxide layer MOL may include an oxide of the second metal M2. In example embodiments, the metal oxide layer MOL may further include an oxide of the first metal M1.

In example embodiments, a composition ratio of the second metal M2 in the metal oxide layer MOL may be greater than a composition ratio of the second metal M2 in the metal layer ML. The composition ratio of the second metal M2 may refer to a proportion of the second metal M2 relative to the first metal M1 in the metal oxide layer MOL or in the metal layer ML.

In example embodiments, the first metal M1 may be derived from a first upper electrode 280. In example embodiments, the second metal M2 may be derived from a second upper electrode 290 or a capping pattern 270.

The first metal M1 may include, e.g., titanium. The second metal M2 may include, e.g., tantalum, ruthenium, etc.

The lower electrode contact 130 may extend through the barrier layer 110 and the first insulating interlayer 120, and may contact a lower surface of lower electrode 210. In example embodiments, a plurality of lower electrode contacts 130 may be spaced apart from each other in each of the first and second directions D1 and D2 corresponding to the memory cells.

FIG. 1 shows that a horizontal width of the lower electrode contact 130 is substantially constant in the third direction D3, however, the disclosed concepts are not limited thereto. For example, the horizontal width of the lower electrode contact 130 may increase or decrease as a distance from the upper surface of the substrate 100 increases in the third direction D3.

In example embodiments, the lower electrode contact 130 may include a metal pattern and a barrier pattern covering a lower surface and a sidewall of the metal pattern. The metal pattern may include a metal, e.g., tungsten, copper, etc., and the barrier pattern may include a metal nitride, e.g., titanium nitride, tantalum nitride, tungsten nitride, etc.

The memory cells may be disposed on the lower electrode contacts 130, respectively. Thus, a plurality of memory cells may be disposed in each of the first and second directions D1 and D2, and may form a memory cell array.

Each of the memory cells may include a lower electrode 210, a seed pattern 220, an MTJ structure 260, a capping pattern 270 and an upper electrode structure 300 sequentially stacked on the lower electrode contact 130 in the third direction D3. Each of the memory cells may include a lower surface facing the upper surface of the substrate 100, an upper surface opposite to the lower surface, and a sidewall connecting the lower and upper surfaces to each other. In example embodiments, the sidewall of each of the memory cells may be slanted with respect to the upper surface of the substrate 100.

FIG. 1 shows that a horizontal width of the memory cell decreases as a distance from the upper surface of the substrate 100 increases in the third direction D3, however, the disclosed concepts are not limited thereto. Thus, a vertical cross-section of the memory cell may have various geometrical shapes, e.g., a tapered shape, a rectangular shape, etc., according to the order of the manufacturing processes, process conditions, design requirements, etc.

The lower electrode 210 may be disposed on the lower electrode contact 130. The lower electrode 210 may include a metal nitride, e.g., titanium nitride, tantalum nitride, etc.

The seed pattern 220 may be disposed on the lower electrode 210. The seed pattern 220 may include, e.g., NiFeCr, Ta/Ru, etc. The seed pattern 220 may control crystal growth and orientation of a fixed pattern 230 and a free pattern 250 of the MTJ structure 260.

The MTJ structure 260 may include the fixed pattern 230, a tunnel barrier pattern 240 and a free pattern 250 sequentially stacked on the seed pattern 220 in the third direction D3.

Each of the fixed pattern 230 and the free pattern 250 may include, e.g., a ferromagnetic material such as CoFe, CoFeB, NiFe, CoFeNi, etc.

The tunnel barrier pattern 240 may include a metal oxide, e.g., magnesium oxide, aluminum oxide, hafnium oxide, titanium oxide, etc.

The operation of the MTJ structure 260 may be based on a spin-dependent tunneling phenomenon. While a magnetization direction of the fixed pattern 230 is fixed, a magnetization direction of the free pattern 250 may be changed by an external magnetic field or by spin-transfer torque. When the magnetization directions of the free pattern 250 and the fixed pattern 230 are parallel, the MTJ structure 260 is in a low-resistance state, and when they are anti-parallel, the MTJ structure 260 is in a high-resistance state. The different resistance states may be utilized to store binary data (‘0’ and ‘1’). A data read operation may be performed by applying a current to the MTJ structure 260 and measuring a resistance, and a data write operation may be performed by applying a current to change the magnetization direction of the free pattern 250.

The capping pattern 270 may be disposed on the MTJ structure 260. The capping pattern 270 may include, e.g., ruthenium, tantalum, tantalum boride, etc. In example embodiments, the capping pattern 270 may include the second metal M2 or a boride of the second metal M2. The capping pattern 270 may protect the MTJ structure 260, and enhance a contact between the MTJ structure 260 and the upper electrode structure 300.

The upper electrode structure 300 may include a first upper electrode 280 and a second upper electrode 290 sequentially stacked on the MTJ structure 260 in the third direction D3. The upper electrode 280 may include a metal nitride, e.g., titanium nitride. The second upper electrode 290 may include a metal nitride, e.g., tantalum nitride. In example embodiments, the first upper electrode 280 may include a nitride of the first metal M1. In example embodiments, the second upper electrode 290 may include a nitride of the second metal M2.

The protective layer structure 370 may include a first protective layer 350 and a second protective layer 360. The first protective layer 350 may be disposed on sidewalls of the memory cells and the sidewall of the trench TR. The metal layer ML may be disposed between the sidewall of the trench TR and the first protective layer 350. That is, the first protective layer 350 may be disposed on the sidewalls of the memory cells and a surface of the metal layer ML.

The second protective layer 350 may be disposed on upper surfaces of the memory cells, an outer sidewall of the first protective layer 350 and the bottom of the trench TR. The metal oxide layer MOL may be disposed between the bottom of the trench TR and the second protective layer 360. That is, the second protective layer 360 may be disposed on the upper surfaces of the memory cells, the outer sidewall of the first protective layer 350, and a surface of the metal oxide layer MOL.

Each of the first and second protective layers 350 and 360 may include an insulating nitride, e.g., silicon nitride. FIG. 2 shows that a boundary of the first and second protective layers 350 and 360 is illustrated as being distinguishable, however, the disclosed concepts are not limited thereto. When the first and second protective layers 350 and 360 include substantially the same material, the boundary between the first and second protective layers 350 and 360 may not be distinguishable.

In the MRAM device, if the metal layer ML is disposed on a surface of the first insulating interlayer 120, electrical short may occur between neighboring memory cells.

However, in example embodiments, the metal layer ML may be at least partially oxidized to form the metal oxide layer MOL. Thus, the electrical short between the neighboring memory cells due to the metal layer ML may be reduced.

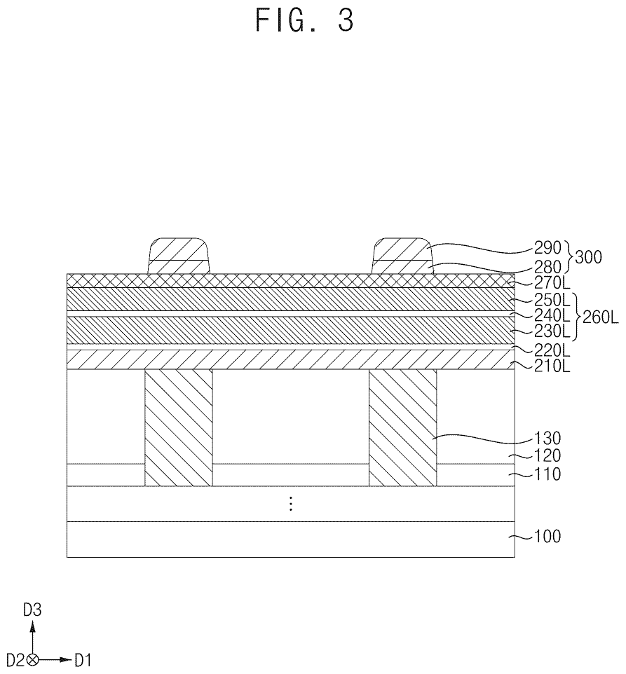

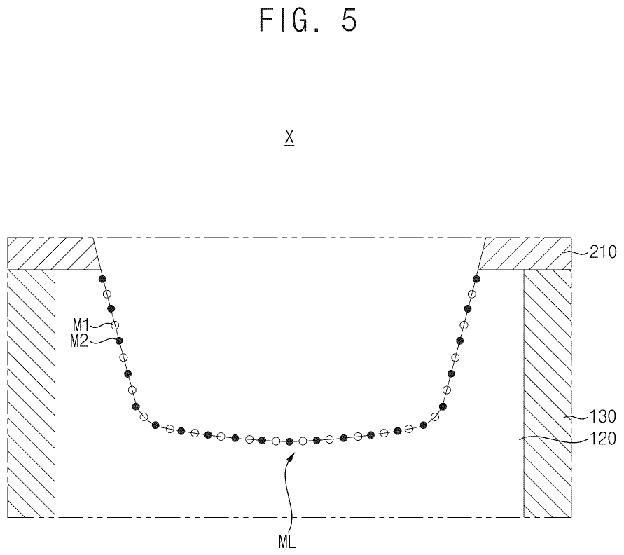

FIGS. 3 to 11 are cross-sectional views illustrating a method of manufacturing an MRAM device in accordance with example embodiments. FIGS. 5, 7, 9 and 11 are enlarged cross-sectional views of region X of corresponding cross-sectional views, respectively.

Referring to FIG. 3, a barrier layer 110 and a first insulating interlayer 120 may be sequentially formed on a substrate 100.

Various types of elements (not shown), e.g., transistors, contact plugs, wirings, vias, etc., may be disposed between an upper surface of the substrate 100 and a lower surface of the barrier layer 110.

A lower electrode contact 130 may be formed through the first insulating interlayer 120 and the barrier layer 110. In example embodiments, a plurality of lower electrode contacts 130 may be formed to be spaced apart from each other in each of the first and second directions D1 and D2.

A lower electrode layer 210L, a seed layer 220L, an MTJ layer structure 260L, a capping layer 270L and an upper electrode layer structure may be sequentially formed on the first insulating interlayer 120 and the lower electrode contact 130. The MTJ layer structure 260 may include a fixed layer 230L, a tunnel barrier layer 240L and a free layer 250L sequentially stacked on the seed layer 220L in the third direction D3. The upper electrode layer structure may include a first upper electrode layer and a second upper electrode layer sequentially stacked on the capping layer 270L in the third direction D3.

The lower electrode layer 210L may include a metal nitride, e.g., titanium nitride, tantalum nitride, etc. The seed layer 220L may include, e.g., NiFeCr, Ta/RU, etc.

Each of the fixed layer 230L and the free layer 250L may include, e.g., a ferromagnetic material. The tunnel barrier layer 240L may include a metal oxide, e.g., magnesium oxide, aluminum oxide, hafnium oxide, titanium oxide, etc.

The capping layer 270L may include, e.g., ruthenium, tantalum, tantalum boride. In example embodiments, the capping layer 270L may include a second metal M2 or a boride of the second metal M2.

The first upper electrode layer may include a metal nitride, e.g., titanium nitride. The second upper electrode layer may include a metal nitride, e.g., tantalum nitride. In example embodiments, the first upper electrode layer may include a nitride of a first metal M1. In example embodiments, the second upper electrode layer may include a nitride of the second metal m2.

The upper electrode layer structure including the first and second upper electrode layer may be patterned to form a plurality of upper electrode structures 300. By the patterning process, the first and second upper electrode layers may be divided into a plurality of first upper electrodes 280 and a plurality of second upper electrodes 290. Each of the upper electrode structures 300 may include the first upper electrode 280 and the second upper electrode 290 sequentially stacked on the capping layer 270L in the third direction D3. By the patterning process, an upper surface of the capping layer 270L may be exposed. The capping layer 270L may protect the MTJ layer structure 260L during the patterning process.

In example embodiments, the upper electrode structures 300 may be formed to be spaced apart from each other in each of the first and second directions D1 and D2.

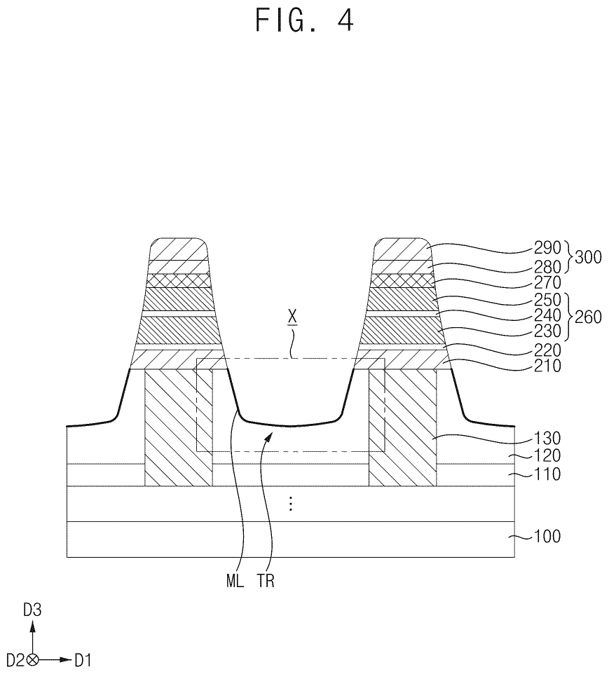

Referring to FIGS. 4 and 5, a first etching process may be performed on the capping layer 260L, the MTJ layer structure 260, the seed layer 220L and the lower electrode layer 210L using the upper electrode structure 300 as an etching mask.

The first etching process may include, e.g., an ion beam etching (IBE) process.

By the first etching process, the capping layer 270L, the MTJ layer structure 260L, the seed layer 220L and the lower electrode layer 210L may be divided into a plurality of capping patterns 270, a plurality of MTJ structures 260, a plurality of seed patterns 220 and a plurality of lower electrodes 210, respectively. The fixed layer 230L, the tunnel barrier layer 240L and the free layer 250L of the MTJ layer structure 260L may be divided into a plurality of fixed patterns 230, a plurality of tunnel barrier patterns 240 and a plurality of free patterns 250, respectively. Each of the MTJ structures 260 may include the fixed pattern 230, the tunnel barrier pattern 240 and the free pattern 250 sequentially stacked on the seed pattern 220 in the third direction D3.

The lower electrode 210, the seed pattern 220, the MTJ structure 260, the capping pattern 270 and the upper electrode structure 300 sequentially stacked on the lower electrode contact 130 in the third direction D3 may collectively form a memory cell. In example embodiments, a plurality of memory cells may be formed to be spaced apart from each other in each of the first and second directions D1 and D2, which may form a memory cell array.

During the first etching process, an upper portion of the first insulating interlayer 120 may also be etched. Thus, a trench TR may be formed on the first insulating interlayer 120. The trench TR may extend from an upper surface of the first insulating interlayer 120 into an inside of the first insulating interlayer 120, and may include a bottom and a sidewall. The bottom of the trench TR may be lower than the upper surface of the first insulating interlayer 120. The sidewall of the trench TR may connect the bottom of the trench TR to the upper surface of the first insulating interlayer 120.

During the first etching process, the first and second metals M1 and M2 derived from the upper electrode structure 300 or the capping pattern 270 may be redeposited on the bottom and the sidewall of the trench TR o form a metal layer ML. The metal layer ML may be formed to at least partially cover the bottom and the sidewall of the trench TR.

The first metal M1 may include, e.g., titanium, and the second metal M2 may include, e.g., tantalum, ruthenium, etc.

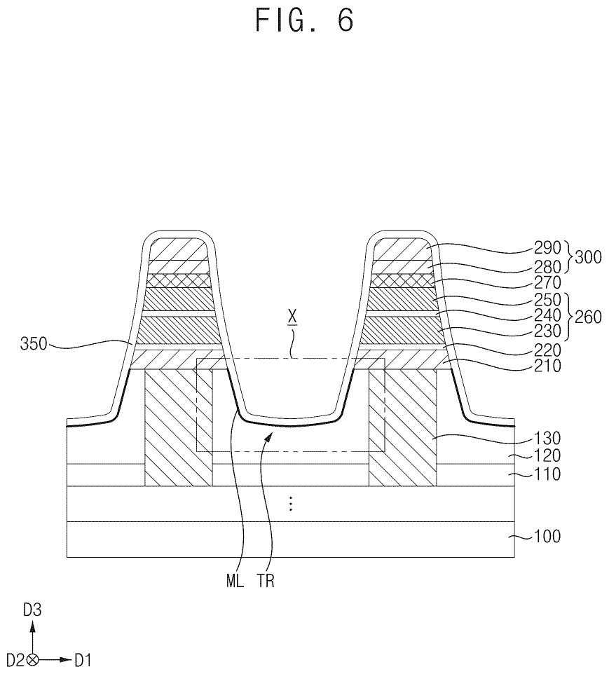

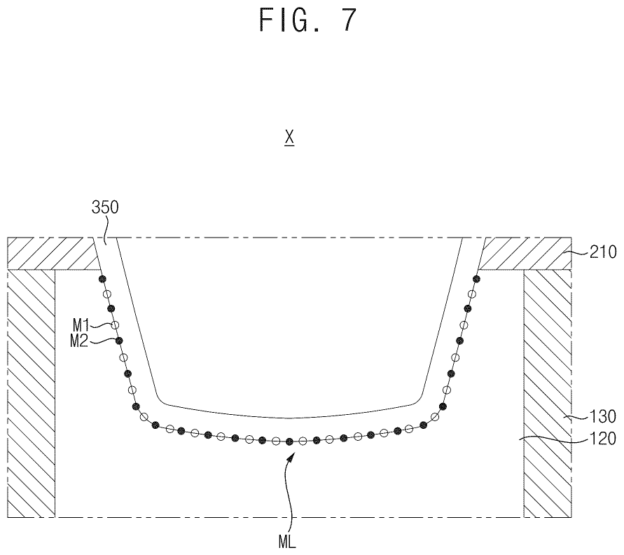

Referring to FIGS. 6 and 7, a first protective layer 350 may be formed on the bottom and the sidewall of the trench TR on the first insulating interlayer 120 and on a sidewall and an upper surface of the memory cell.

Thus, a surface of the metal layer ML on the bottom and the sidewall of the trench TR may be covered by the first protective layer 350.

The first protective layer 350 may include an insulating nitride, e.g., silicon nitride.

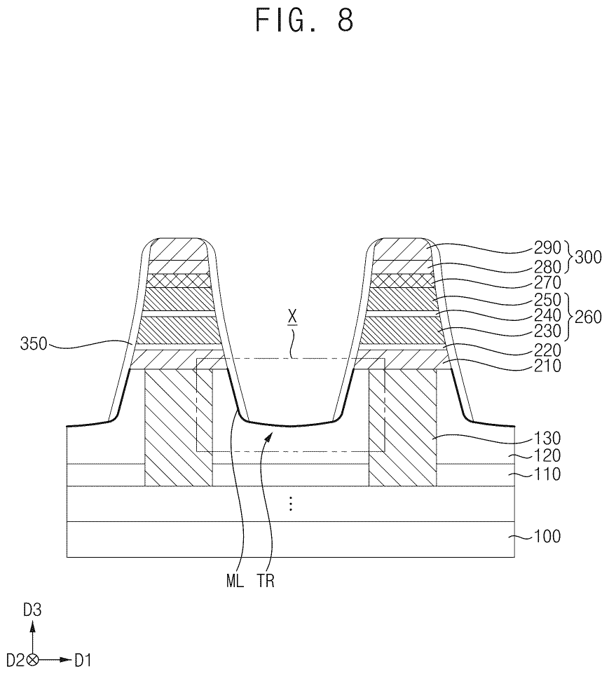

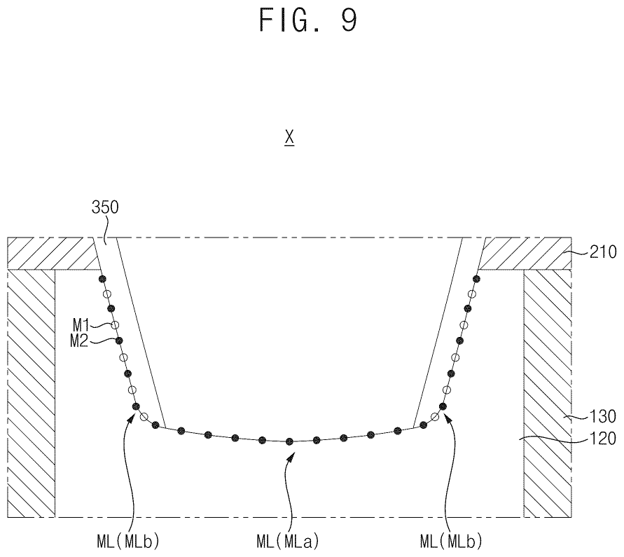

Referring to FIGS. 8 and 9, an anisotropic etching process may be performed on the first protective layer 350.

Thus, a portion of the first protective layer 350 on the upper surface of the memory cell and on the bottom of the trench TR may be removed so that the surface of the metal layer ML on the bottom of the trench TR may be at least partially exposed. In example embodiments, during the anisotropic etching process, the metal layer ML may also be partially removed.

In example embodiments, after the anisotropic etching process, the first protective layer 350 may cover the sidewall of the memory cell and the sidewall of the trench TR.

A portion of the metal layer ML not covered by the first protective layer 350 may be referred to as a first portion MLa, and a portion of the metal layer ML covered by the first protective layer 350 may be referred to as a second portion MLb.

A cleaning process may be performed to at least partially remove the first portion MLa of the metal layer ML. In example embodiments, the second upper electrode 290 may have a relatively low etch rate and the first portion MLa of the metal layer ML may have a relatively high etch rate during the cleaning process. Thus, the upper electrode structure 300 including the second upper electrode 290 may not be removed during the cleaning process.

In example embodiments, the first metal M1 may have a relatively high etch rate and the second metal M2 may have a relatively low etch rate during the cleaning process. Thus, a composition ratio of the second metal M2 in the first portion MLa of the metal ML may be greater than a composition ratio of the second metal M2 in the second portion MLb of the metal ML. The composition ratio of the second metal M2 may refer to a ratio of the second metal M2 with respect to the first metal M1 in the metal layer ML or in a portion of the metal layer ML.

FIGS. 8 and 9 show that the first metal M1 is entirely removed from the first portion MLa of the metal layer ML by the cleaning process, however, in some embodiments, the first metal M1 may partially remain after the cleaning process.

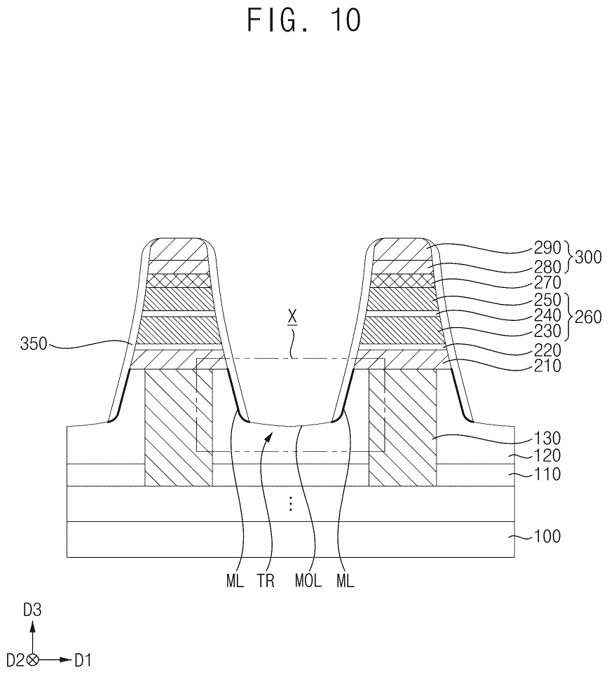

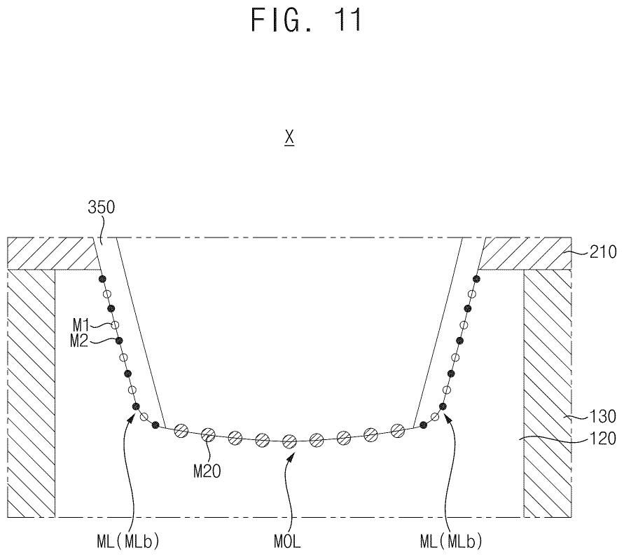

Referring to FIGS. 10 and 11, an oxidation process may be performed on the first portion MLa of the metal layer ML.

Thus, the first portion MLa of the metal layer ML may be converted into a metal oxide layer MOL including a second metal oxide M2O, which may be an oxide of the second metal M2.

In some embodiments, the metal oxide layer MOL may include an oxide of the first metal M1 that remains after the cleaning process.

In example embodiments, the oxidation process may include an atomic layer deposition (ALD) oxidation process on the first portion MLa of the metal layer ML. An oxygen source gas used in the oxidation process may include, e.g., ozone (O₃), oxygen (O₂) plasma, water (H₂0), etc.

Referring to FIG. 1 and again, a second protective layer 360 may be formed on an upper surface of the memory cell, an outer sidewall of the first protective layer 350 and a surface of the metal oxide layer MOL.

The second protective layer 350 may include an insulating nitride, e.g., silicon nitride.

The first and second protective layers 350 and 360 may collectively form a protective layer structure 370.

In the method of manufacturing the MRAM device, when the etching process for the capping layer 270L, the MTJ layer structure 260L, the seed layer 220L and the lower electrode layer 210L is performed using the upper electrode structure 300 as an etching mask, the metal layer ML that may be derived from the upper electrode structure 300 and the capping pattern 270 may be formed on a surface of the first insulating interlayer 120. The cleaning process may be performed on the metal layer ML, and the oxidation process may be performed on the metal layer ML remaining after the cleaning process.

If the metal layer ML remains on the sidewall and the bottom of the trench TR on the first insulating interlayer 120, electrical short may occur between neighboring memory cells. However, in example embodiments, the cleaning process and the oxidation process may be performed so as to reduce the electrical short between neighboring memory cells.

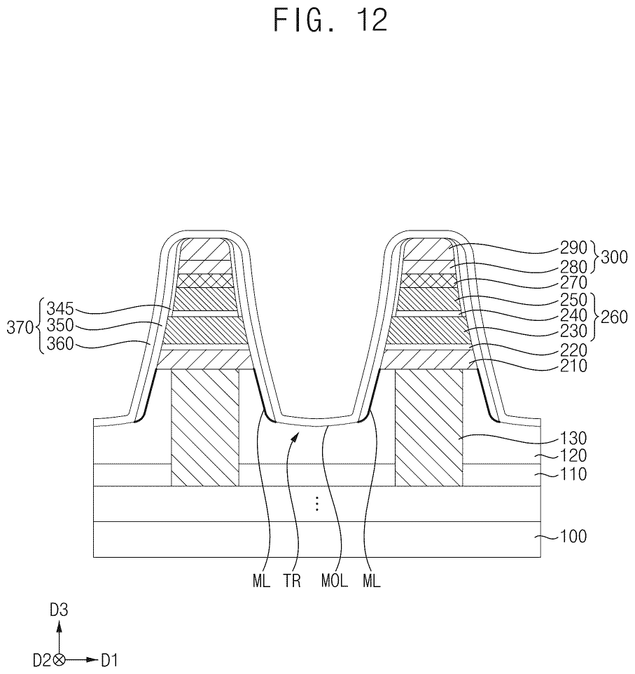

FIG. 12 is a cross-sectional view illustrating an MRAM device in accordance with example embodiments. This MRAM device may be substantially the same as or similar to that of FIGS. 1 and 2, except for the shapes of the protective layer structure 370 and the memory cell, and thus repeated explanations are omitted herein.

Referring to FIG. 12, the protective layer structure 370 may further include a third protective layer 345.

The third protective layer 345 may cover an upper surface of the fixed pattern 230, a sidewall of the tunnel barrier pattern 240, a sidewall of the free pattern 250, a sidewall of the capping pattern 270, and a sidewall and an upper surface of the upper electrode structure 300.

The first protective layer 350 may cover an outer sidewall of the third protective layer 350, a sidewall of the fixed pattern 230, a sidewall of the seed pattern 220, a sidewall of the lower electrode 210, and the surface of the metal layer ML. The second protective layer 360 may cover the upper surface of the upper electrode structure 300, the outer sidewall of the first protective layer 350 and the surface of the metal oxide layer MOL. That is, the third protective layer 345, the first protective layer 350 and the second protective layer 360 may be sequentially stacked on the sidewall of the memory cell.

The third protective layer 345 may cover the upper surface of the fixed pattern 230 and the sidewall of the tunnel barrier pattern 240. Thus, the sidewall of the fixed pattern 230 may be spaced apart from the sidewall of the tunnel barrier pattern 240 by the third protective layer 345.

In example embodiments, a width in the horizontal direction of the upper surface of the fixed pattern 230 may be greater than a width in the horizontal direction of a lower surface of the tunnel barrier pattern 240. In example embodiments, a planar area of the upper surface of the fixed pattern 230 may be greater than a planar area of the lower surface of the tunnel barrier pattern 240.

The third protective layer 345 may include an insulating nitride, e.g., silicon nitride. In the drawing, a boundary between the first and third protective layers 350 and 345 is illustrated as being distinguishable, however, the disclosed concepts are not limited thereto. In some embodiments, the first and third protective layers 350 and 345 may include substantially the same material, and the boundary between the first and third protective layers 350 and 345 may not be identifiable.

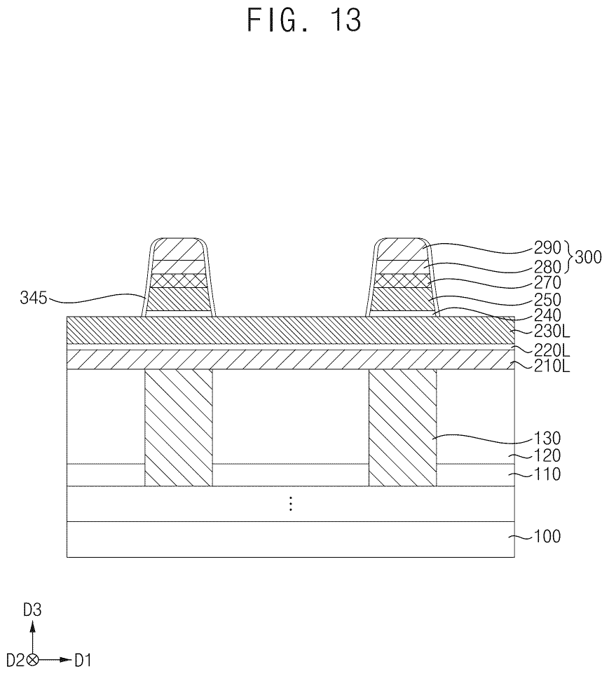

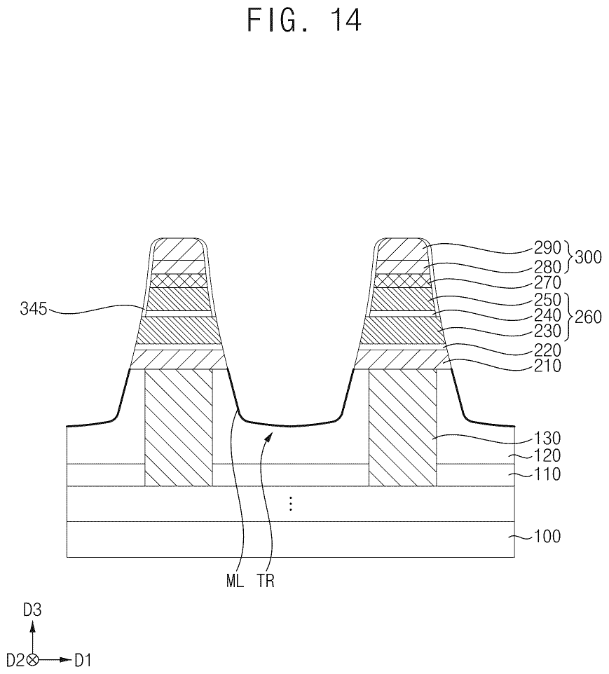

FIGS. 13 and 14 are cross-sectional views illustrating a method of manufacturing an MRAM device in accordance with example embodiments. This method may include processes substantially the same as or similar to those illustrated with reference to FIGS. 3 to 11 and FIGS. 1 and 2, and thus repeated explanations thereof are omitted herein.

Referring to FIG. 13, processes substantially the same as or similar to those illustrated with reference to FIG. 3 may be performed, and instead of the first etching process, a second etching process may be performed using the upper electrode structure 300 as an etching mask to pattern the capping layer 270L, the free layer 250L and the tunnel barrier layer 240L.

By the second etching process, the capping layer 270L, the free layer 250L and the tunnel barrier layer 240L may be divided into the capping patterns 270, the free patterns 250 and the tunnel barrier patterns 240, respectively.

Referring to FIG. 14, a third protective layer 345 may be formed on the upper surface and the sidewall of the upper electrode structure 300, the sidewall of the capping pattern 270, the sidewall of the free pattern 250, the sidewall of the tunnel barrier pattern 240 and the upper surface of the fixed layer 230L.

An anisotropic etching process may be performed on the third protective layer 340. Thus, the third protective layer 340 may cover the sidewall of the upper electrode structure 300, the sidewall of the capping pattern 270, the sidewall of the free pattern 250, the tunnel barrier pattern 240 and a portion of the upper surface of the fixed layer 230L.

A third etching process may be performed using the upper electrode structure 300 and the third protective layer 340 as an etching mask to pattern the fixed layer 230L, the seed layer 220L and the lower electrode layer 210L. By the third etching process, the fixed layer 230L, the seed layer 220L and the lower electrode layer 210L may be divided into the fixed patterns 230, the seed patterns 220 and the lower electrodes 210, respectively.

During the third etching process, the sidewall of the tunnel barrier pattern 240 may be covered by the third protective layer 345, and a metal from the lower electrode 210 may be prevented from being redeposited onto the sidewall of the tunnel barrier pattern 240. That is, by the existence of the third protective layer 345, conductive particles generated from the lower electrode 210 during the third etching process may be separated from the tunnel barrier pattern 240, so that the electric short between the free pattern 250 and the fixed pattern 230 may be effectively prevented.

Processes substantially the same as or similar to those illustrated with reference to FIGS. 6 to 11 and FIGS. 1 and 2 may be performed to complete the fabrication of the MRAM device.

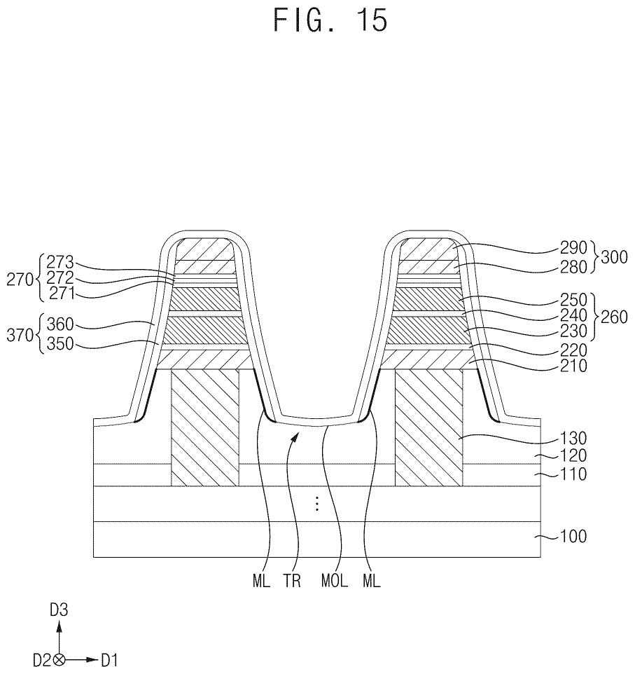

FIG. 15 is a cross-sectional view illustrating an MRAM device in accordance with example embodiments. This MRAM device may be substantially the same as or similar to that of FIGS. 1 and 2, except for the capping pattern 270. Thus, repeated explanations are omitted herein.

Referring to FIG. 15, the capping pattern 270 may include a first sub-capping pattern 271, a second sub-capping pattern 272 and a third sub-capping pattern 273 sequentially stacked in the third direction D3 on the MTJ structure 260.

The first sub-capping pattern 271 may include, e.g. ruthenium. The second sub-capping pattern 272 may include, e.g., tantalum, tantalum boride, etc. The third sub-capping pattern 273 may include, e.g., ruthenium.

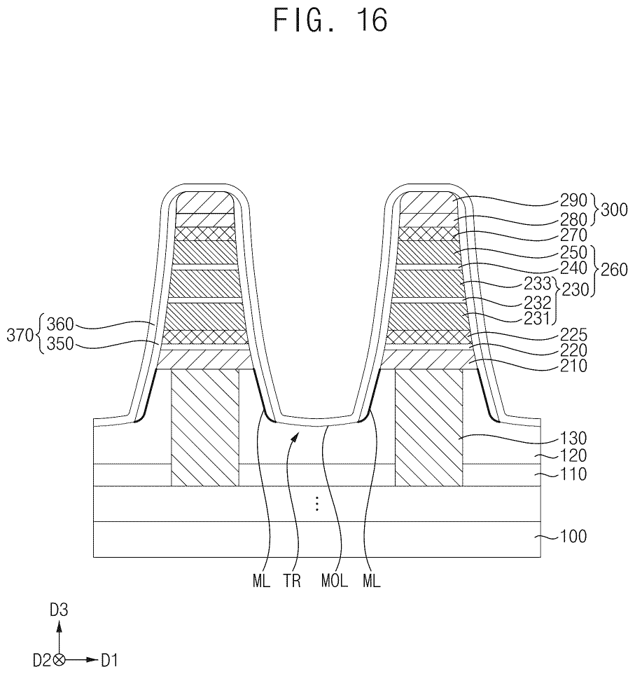

FIG. 16 is a cross-sectional view illustrating an MRAM device in accordance with example embodiments. This MRAM device may be substantially the same as or similar to that of FIGS. 1 and 2, except for the fixed pattern 230 and further including an anti-ferromagnetic pattern. Thus, repeated explanations are omitted herein.

Referring to FIG. 16, the fixed pattern 230 may have a synthetic anti-ferromagnet (SAF) structure.

Particularly, the fixed pattern 230 may include a first magnetic pattern 231, a first non-magnetic pattern 232 and a second magnetic pattern 233 sequentially stacked.

In the fixed pattern 230 having such an SAF structure, for example, anti-ferromagnetic coupling (AFC) characteristics due to an Ruderman-Kittel-Kasuya-Yosida (RKKY) interaction may be exhibited. In this case, magnetization directions of the first magnetic pattern 231and the second magnetic pattern 233 may be aligned anti-parallel to each other, such that a total magnetization of the fixed pattern 230 may be minimized. The first and second magnetic patterns 231 and 233 may have fixed magnetization directions.

Each of the first and second magnetic patterns 231 and 233 may include a ferromagnetic metal, e.g., cobalt, iron, nickel, etc., or an alloy thereof. Particularly, each of the first and second magnetic patterns 231 and 233 may include, e.g., CoFe, CoFeB, NiFe, CoNiFe, CoPt, CoNi, etc. Additionally, each of the first and second magnetic patterns 231 and 233 may include a compound containing a rare-earth element, for example, NdFeB or SmCo.

The non-magnetic pattern 232 may include a non-magnetic metal, e.g., ruthenium, iridium, rhodium, platinum, tantalum, tungsten, titanium, chrome, copper, silver, gold, aluminum, etc., or an alloy thereof. The first non-magnetic pattern 232 may include a material that may induce RKKY coupling, e.g., ruthenium, iridium, rhodium, etc.

The anti-ferromagnetic pattern 225 may be disposed between the fixed pattern 230 and the seed pattern 220 of the MTJ structure 260. The anti-ferromagnetic pattern 225 may serve to pin the magnetization direction of the fixed pattern 230, and may enhance thermal stability through an exchange bias effect. Through exchange coupling generated at an interface between the anti-ferromagnetic pattern 225 and the first magnetic pattern 231, the magnetization direction of the first magnetic pattern 231 may be fixed in a predetermined direction even in the absence of an external magnetic field. Accordingly, the fixed pattern 230 of the MTJ structure 260 may maintain a stable reference magnetization state.

The anti-ferromagnetic pattern 225 may include an anti-ferromagnetic material, e.g., IrMn, PtMn, FeMn, NiMn, PtPdMn, IrMnCr, etc.

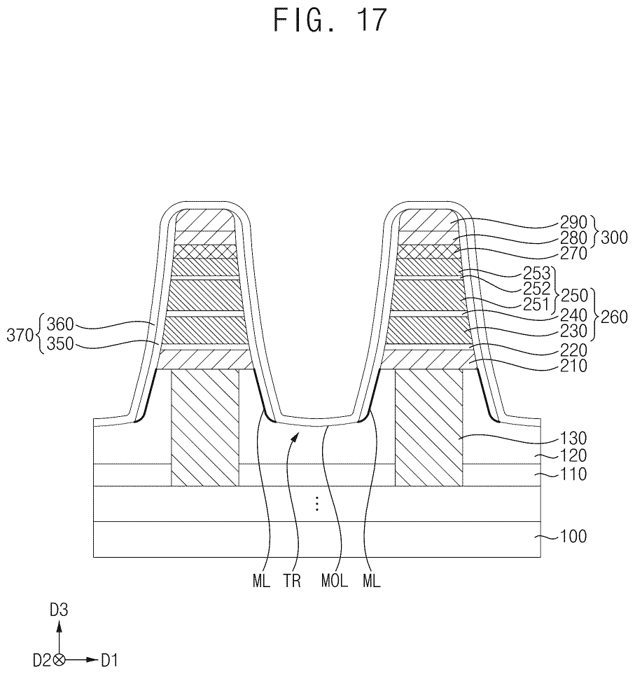

FIG. 17 is a cross-sectional view illustrating an MRAM device in accordance with example embodiments. This MRAM device may be substantially the same as or similar to that of FIGS. 1 and 2, except for the free pattern 250. Thus, repeated explanations are omitted herein.

Referring to FIG. 17, the free pattern 250 of the MTJ structure 260 may have an SAF structure.

Particularly, the free pattern 250 may include a third magnetic pattern 251, a second non-magnetic pattern 252 and a fourth magnetic pattern 253 sequentially stacked in the third direction D3.

In the free pattern 250 having such an SAF structure, magnetization directions of the third magnetic pattern 251 and the fourth magnetic pattern 253 may be aligned anti-parallel to each other by an RKKY interaction. In this case, the magnetization direction of one of the third and fourth magnetic patterns 251 and 253 may be changed by an external magnetic field or spin-transfer torque, and the other magnetic pattern may also switch its magnetization direction while maintaining the anti-parallel state therewith.

Each of the third and fourth magnetic patterns 251 and 253 may include a ferromagnetic metal, e.g., cobalt, iron, nickel, etc., or an alloy thereof. Particularly, each of the first and second magnetic patterns 231 and 233 may include, e.g., CoFe, CoFeB, NiFe, CoNiFe, CoPt, CoNi, etc. Additionally, each of the first and second magnetic patterns 231 and 233 may include a compound containing a rare-earth element, e.g., NdFeB, SmCo, etc.

The second non-magnetic pattern 252 may include a non-magnetic metal, e.g., ruthenium, iridium, rhodium, platinum, tantalum, tungsten, titanium, chrome, copper, silver, gold, aluminum, etc., or an alloy thereof. Particularly, the second non-magnetic pattern 252 may include a material that may induce RKKY coupling, e.g., ruthenium, iridium, rhodium, etc.

The third and fourth magnetic patterns 251 and 253 may include materials similar to those of the first and second magnetic patterns 231 and 233, respectively, of FIG. 13, however, depending on the functional differences between the fixed pattern 230 and the free pattern 250, layer thicknesses, compositional ratios, interface treatments, and the like may be different. For example, the magnetic patterns of the fixed pattern 230 may be optimized to achieve strong exchange coupling with the anti-ferromagnetic pattern 225, whereas the magnetic patterns of the free pattern 250 may be adjusted to realize a long switching current and high magnetization reversal efficiency. Additionally, the first and second non-magnetic patterns 232 and 252 may also be designed to have different thicknesses, respectively, in order to determine the strength of RKKY coupling.

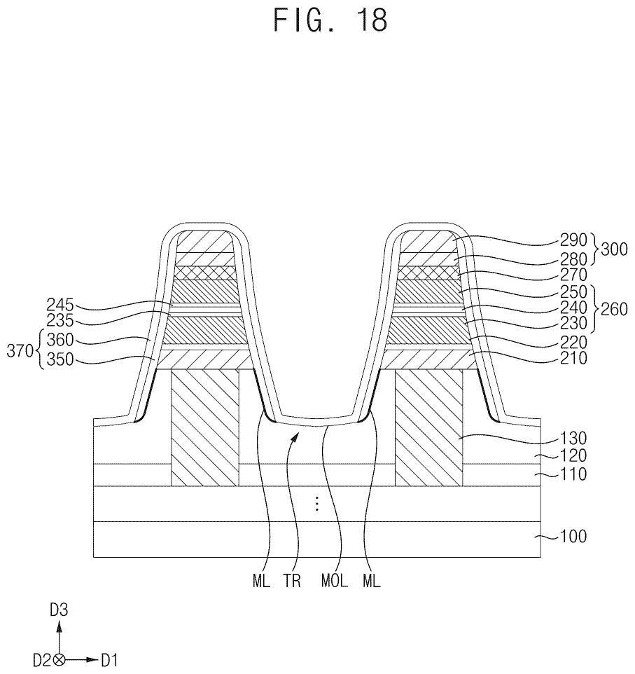

FIG. 18 is a cross-sectional view illustrating an MRAM device in accordance with example embodiments. This MRAM device may be substantially the same as or similar to that of FIGS. 1 and 2, except for further including polarization enhancement patterns 235 and 245. Thus, repeated explanations are omitted herein.

Referring to FIG. 18, the first polarization enhancement pattern 235 may be disposed between the fixed pattern 230 and the tunnel barrier pattern 240, and the second polarization enhancement pattern 245 may be disposed between the tunnel barrier pattern 240 and the free pattern 250.

The first and second polarization enhancement patterns 235 and 245 may improve interfacial characteristics with the tunnel barrier pattern 240 and enhance spin polarization, thereby increasing a tunneling magnetoresistance ratio of the MTJ structure 260. Additionally, the first and second polarization enhancement patterns 235 and 245 may prevent elemental diffusion during a heat treatment process and improve interfacial quality by enhancing crystallographic matching with the tunnel barrier pattern 240.

In the drawing, the first and second polarization enhancement patterns 235 and 245 may be disposed on upper and lower surfaces of the tunnel barrier pattern 230, however, the disclosed concepts are not limited thereto. That is, the MRAM device may include only one of the first and second polarization enhancement patterns 235 and 245.

The first and second polarization enhancement patterns 235 and 245 may include, e.g., cobalt, iron, nickel, etc., or an alloy thereof.

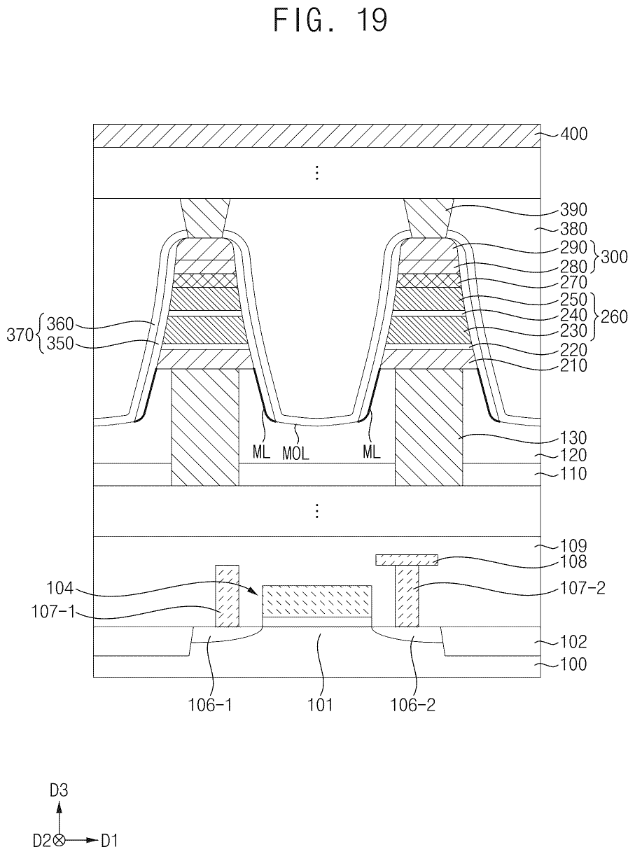

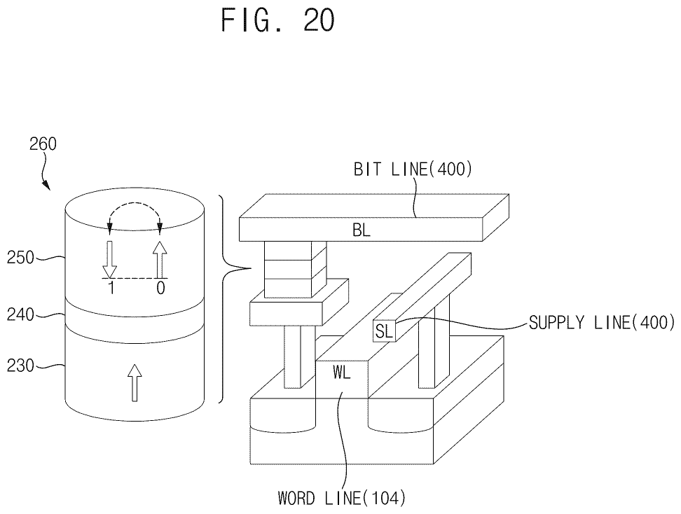

FIGS. 19 and 20 are a cross-sectional view and a perspective view, respectively, illustrating an MRAM device in accordance with example embodiments. This MRAM device may be an application of the structures shown in FIGS. 1 and 2 to a STT-MRAM device, and repeated explanations are omitted herein.

Referring to FIGS. 19 and 20, the MRAM device may include an active pattern 101, an isolation pattern 102, a transistor 103, source/drain contacts 107-1 and 107-2, a supply line 108, second and third insulating interlayers 109 and 380, an upper contact 390 and a bit line 400.

The active pattern 101 may protrude from the substrate 100 upwardly in the third direction D3. The active pattern 101 may be formed by partially removing an upper portion of the substrate 100, and thus may be integrally formed with the substrate 100.

The isolation pattern 102 may cover a sidewall of the active pattern 101. The isolation pattern 102 may include an oxide, e.g., silicon oxide.

The transistor 103 may include a gate structure 104 and source/drain regions 106-1 and 106-2 at upper portions of the active pattern 101 adjacent to the gate structure 104. The gate structure 104 may serve as a word line, or may be electrically connected thereto.

The gate structure 104 may include a gate insulation pattern and a gate electrode sequentially stacked on an upper surface of the active pattern 101 in the third direction D3.

The gate insulation pattern may include an oxide, e.g., silicon oxide, hafnium oxide, zirconium oxide, aluminum oxide, or a combination thereof. The gate electrode may include a metal, e.g., tungsten, titanium, molybdenum, etc., a metal nitride, e.g., titanium nitride, tungsten nitride, tantalum nitride, etc., or a combination thereof. The source/drain regions 106-1 and 106-2 may further include, e.g., n-type or p-type impurities.

The source/drain contacts 107-1 and 107-2 may contact upper surfaces of the source/drain regions 106-1 and 106-2, respectively, and may be electrically connected thereto. Each of the source/drain contacts 107-1 and 107-2 may include a metal, e.g., tungsten, titanium, tantalum, etc., a metal nitride, e.g., titanium nitride, tantalum nitride, tungsten nitride, etc., or an alloy thereof.

The lower electrode contact 130 may be electrically connected to the source/drain contact 107-1, and the supply line 108 may be electrically connected to the source/drain contact 107-2.

The second insulating interlayer 109 may cover the active pattern 101, the isolation pattern 102, the transistor 103, the source/drain contact 107-1 and 107-2, and the supply line 108. The second insulating interlayer 109 may include an oxide, e.g., silicon oxide.

The third insulating interlayer 380 may be disposed on the protective layer structure 370, and may fill a space between the memory cells. The third insulating interlayer 320 may include an oxide, e.g., silicon oxide.

The upper electrode contact 390 may extend through the third insulating interlayer 380 and the protective layer structure 370, and may contact an upper surface of the upper electrode structure 300. In example embodiments, a plurality of upper electrode contacts 390 may be spaced apart from each other in each of the first and second directions D1 and D2.

In the drawing, a width in the horizontal direction of the upper electrode contact 390 increases as a distance from the upper surface of the substrate 100 increases in the third direction D3, however, the disclosed concepts are not limited thereto. That is, the width in the horizontal direction of the upper electrode contact 390 may be substantially constant or decreases as the distance from the upper surface of the substrate 100 increases in the third direction D3.

In example embodiments, the upper electrode contact 390 may include a metal pattern and a barrier pattern covering a lower surface and a sidewall thereof. The metal pattern may include a metal, e.g., tungsten, copper, etc., and the barrier pattern may include a metal nitride, e.g., titanium nitride, tantalum nitride, tungsten nitride, etc.

The bit line 400 may extend on the memory cells. The bit line 400 may be electrically connected to at least one of the memory cells including the MTJ structure 260 through the upper electrode contact 390

Data write and read operations of the STT-MRAM device may be performed, as follows. During a data write operation, a current flows between the bit line 400 and the supply line 108. Depending on a direction of the current, a magnetization direction of the free pattern 250 of the MTJ structure 260 is determined. For example, when the current flows from the bit line 400 toward the supply line 108, the magnetization direction of the free pattern 250 may be aligned parallel to that of the fixed pattern 230, thereby exhibiting a low-resistance state. Conversely, when the current flows from the supply line 108 toward the bit line 400, the magnetization direction of the free pattern 250 may be aligned anti-parallel to that of the fixed pattern 230, thereby exhibiting a high-resistance state. This behavior is attributed to a spin-transfer torque phenomenon, in which spin angular momentum carried by the current switches the magnetization direction of the free pattern 250.

During a data read operation, a current having a lower magnitude than that used during the write operation is applied between the bit line 400 and the supply line 108 to sense a resistance state of the MTJ structure 260. When magnetization directions of the free pattern 250 and the fixed pattern 230 are parallel to each other, a low-resistance state is exhibited, whereas when the free pattern 250 and the fixed pattern 230 are anti-parallel, a high-resistance state is exhibited. By detecting the resistance difference through a sensing circuit, it is possible to determine whether the stored data is a “0” or a “1.”

The MRAM device and the method of manufacturing the same illustrated with reference to FIGS. 1 to 18 may also be applied to, e.g., toggle MRAM device, spin orbit torque (SOT) MRAM device, voltage-controlled magnetic anisotropy (VCMA) MRAM device, etc.

The MRAM device in accordance with example embodiments may include a lower electrode contact at least partially extending through an insulating interlayer on a substrate; a memory cell including a lower electrode, an MTJ structure, a capping pattern, a first upper electrode and a second upper electrode sequentially stacked; a metal layer at least partially covering a sidewall of a trench that extends from an upper surface of the insulating interlayer adjacent to the memory cell into an inside of the insulating interlayer; a metal oxide layer at least partially covering a bottom of the trench; and a protective layer structure covering a sidewall of the memory cell, a surface of the metal layer and a surface of the metal oxide layer.

In example embodiments, the metal layer may include a first metal and a second metal, and a composition ratio of the second metal with respect to the first metal in the metal oxide layer may be greater than a composition ratio of the second metal with respect to the first metal of in the metal layer.

In example embodiments, the first upper electrode may include a nitride of the first metal, the second upper electrode may include a nitride of the second metal, and the capping pattern may include the second metal or a boride of the second metal.

In example embodiments, the first metal may include titanium, and the second metal may include tantalum or ruthenium.

In example embodiments, the protective layer structure may include a first protective layer covering the sidewall of the memory cell and the surface of the metal layer, and a second protective layer covering an outer sidewall of the first protective layer and the surface of the metal oxide layer.

In example embodiments, each of the first and second protective layers may include silicon nitride.

In example embodiments, the capping pattern may include a first sub-capping pattern, a second sub-capping pattern and a third sub-capping pattern.

In example embodiments, each of the first and third sub-capping patterns may include ruthenium, and the second sub-capping pattern may include tantalum or tantalum boride.

In example embodiments, the MTJ structure may include a fixed pattern, a tunnel barrier pattern and a free pattern.

In example embodiments, the fixed pattern or the free pattern may have a synthetic anti-ferromagnet (SAF) structure.

In example embodiments, the MRAM device may further include a polarization enhancement pattern between the fixed pattern and the tunnel barrier pattern or between the free pattern and the tunnel barrier pattern.

While the present disclosed concepts have been shown and described with reference to example embodiments thereof, it will be understood by those of ordinary skill in the art that various changes in form and details may be made thereto without departing from the spirit and scope of the present disclosed concepts as set forth by the following claims.

What is claimed is:

1. A method of manufacturing an MRAM device comprising:
forming an MTJ layer structure on an insulating interlayer on a substrate;
forming an upper electrode structure on the MTJ layer structure;
performing an etching process using the upper electrode structure as an etching mask to transform the MTJ layer structure into an MTJ structure and to form a trench at an upper portion of the insulating interlayer, such that a metal layer including a metal generated from the upper electrode structure during the etching process and at least partially covering a sidewall and a bottom of the trench is formed;
forming a first protective layer on a sidewall of the upper electrode structure, a sidewall of the MTJ structure and the sidewall of the trench; and
performing an oxidation process on the metal layer to form a metal oxide layer at least partially covering the bottom of the trench.

2. The method according to claim 1, wherein forming the first protective layer includes:
forming the first protective layer on the sidewall of the upper electrode structure, the sidewall of the MTJ structure and the sidewall and the bottom of the trench; and
performing an anisotropic etching process on the first protective layer to at least partially expose a surface of the metal layer on the bottom of the trench.

3. The method according to claim 1, further comprising, after forming the first protective layer and prior to forming the metal oxide layer, performing a cleaning process on the metal layer.

4. The method according to claim 3, wherein:
the upper electrode structure includes a first upper electrode and a second upper electrode sequentially stacked on the MTJ structure, and
an etch rate of the metal layer is greater than an etch rate of the second upper electrode during the cleaning process.

5. The method according to claim 4, wherein the metal oxide layer is formed by performing the oxidation process on the metal layer remaining after the cleaning process.

6. The method according to claim 1, wherein the oxidation process includes an atomic layer deposition (ALD) oxidation process.

7. The method according to claim 1, further comprising, after forming the metal oxide layer, forming a second protective layer on a surface of the metal oxide layer, an outer sidewall of the first protective layer and an upper surface of the upper electrode structure.

8. A method of manufacturing an MRAM device comprising:
forming a lower electrode layer and an MTJ layer structure on an insulating interlayer on a substrate;
forming an upper electrode structure on the MTJ layer structure;
performing an etching process using the upper electrode structure as an etching mask to transform the MTJ layer structure and the lower electrode layer into an MTJ structure and a lower electrode, respectively, and to form a trench at an upper portion of the insulating interlayer, such that a metal layer including a metal generated from the upper electrode structure during the etching process and at least partially covering a sidewall and a bottom of the trench is formed;
forming a first protective layer on an upper surface and a sidewall of the upper electrode structure, a sidewall of the MTJ structure, a sidewall of the lower electrode, and the sidewall and the bottom of the trench;
performing an anisotropic etching process on the first protective layer to expose a first portion of the metal layer on the bottom of the trench; and
performing a cleaning process on the first portion of the metal layer.

9. The method according to claim 8, wherein:
the upper electrode structure includes a first upper electrode and a second upper electrode sequentially stacked on the MTJ structure, and
an etch rate of the metal layer is greater than an etch rate of the second upper electrode during the cleaning process.

10. The method according to claim 8, wherein the bottom of the trench is lower than an upper surface of the insulating interlayer.

11. The method according to claim 8, wherein:
the first portion of the metal layer remains after the cleaning process, and
the method further includes performing an oxidation process on the first portion of the metal layer to form a metal oxide layer.

12. The method according to claim 8, further comprising, after the cleaning process, forming a second protective layer on the upper surface of the upper electrode structure, an outer sidewall of the first protective layer and the bottom of the trench.

13. A method of manufacturing an MRAM device comprising:
forming a lower electrode layer, an MTJ layer structure and a capping layer on an insulating interlayer on a substrate;
forming an upper electrode structure including a first upper electrode and a second upper electrode sequentially stacked on the capping layer;
performing an etching process using the upper electrode structure as an etching mask to transform the capping layer, the MTJ layer structure and the lower electrode layer into a capping pattern, an MTJ structure and a lower electrode, respectively, and to form a trench at an upper portion of the insulating interlayer, such that a metal layer including a first metal and a second metal generated from the capping pattern and the upper electrode structure, respectively, during the etching process and at least partially covering a sidewall and a bottom of the trench is formed;
forming a first protective layer on a sidewall of the upper electrode structure, a sidewall of the capping pattern, a sidewall of the MTJ structure, a sidewall of the lower electrode and the sidewall of the trench;
performing a cleaning process on a first portion of the metal layer on the bottom of the trench; and
performing an oxidation process on the first portion of the metal layer remaining after the cleaning process to form a metal oxide layer,
wherein the first metal of the metal layer is removed during the cleaning process.

14. The method according to claim 13, wherein a composition ratio of the second metal of the first portion of the metal layer is greater than a composition ratio of the second metal of the second portion of the metal layer on the sidewall of the trench.

15. The method according to claim 13, wherein an etch rate of the metal layer is greater than an etch rate of the second upper electrode during the cleaning process.

16. The method according to claim 13, wherein an etch rate of the first metal of the metal layer is greater than an etch rate of the second metal of the metal layer during the cleaning process.

17. The method according to claim 13, wherein:
the first metal is derived from the first upper electrode, and
the second metal is derived from the second upper electrode or the capping pattern.

18. The method according to claim 13, wherein:
the first metal includes titanium, and
the second metal includes tantalum or ruthenium.

19. The method according to claim 13, wherein the oxidation process includes an atomic layer deposition (ALD) process.

20. The method according to claim 13, further comprising forming a second protective layer on an upper surface of the upper electrode structure, an outer sidewall of the first protective layer and the bottom of the trench.
